(19) United States
(12) Patent Application Publication
(10) Pub. No.: US 2012/0256851 A1
(43) Pub. Date: Oct. 11, 2012

(54) TOUCH PANEL AND TOUCH DISPLAY PANEL

(75) Inventors: Po-Hsien Wang, Taichung City (TW); Hsuan-Yang Chen, Hualien County (TW)

(73) Assignees: WINTEK CORPORATION, Taichung City (TW); Wintek Technology(H.K) Ltd., Guangdong Province (CN)

(21) Appl. No.: 13/193,609

(22) Filed: Jul. 29, 2011

(30) Foreign Application Priority Data
Apr. 8, 2011 (TW) 100112224

(51) Int. Cl. G06F 3/041; H03K 17/975

(52) U.S. Cl. 345/173; 200/600

(57) ABSTRACT

A touch panel has an active area and a peripheral area surrounding the active area. The touch panel includes a cover plate, a touch sensing element, a non-black color layer, transmission lines, a reflective pattern layer, and a protection layer. The touch sensing element is on the cover plate and in the active area. The non-black color layer is on the cover plate and in the peripheral area. The transmission lines at a side of the non-black color layer away from the cover plate and in the peripheral area electrically connect the touch sensing element. The reflective pattern layer is configured at the side of the non-black color layer away from the cover plate and at least located in a partial region of the peripheral area not covered by the transmission lines. The protection layer is configured at a side of the transmission lines away from the cover plate.

### CROSS-REFERENCE TO RELATED APPLICATION

This application claims the priority benefit of Taiwan application serial no. 100112224, filed Apr. 8, 2011. The entirety of the above-mentioned patent application is hereby incorporated by reference herein and made a part of this specification.

### BACKGROUND OF THE INVENTION

1. Field of the Invention

The invention relates to a touch panel and a touch display panel. More particularly, the invention relates to a touch panel in which a border is not black and a touch display panel having the touch panel in which a border is not black.

2. Description of Related Art

A touch display apparatus includes a display panel and a touch panel configured on the display panel. A plurality of transmission lines are configured in a peripheral area of the touch panel in order to transmit signals. In the touch display apparatus, a black ink layer is often configured at a location corresponding to the peripheral area, so as to cover the transmission lines. Thereby, the black border is formed in the touch display apparatus.

From the perspective of a user, the black border does not necessarily meet the user's requirement for the exterior of the apparatus. A non-black ink material or a photoresist material can shield light to a satisfactory degree only when the thickness of the non-black ink material or the thickness of the photoresist material is sufficient. Hence, when the non-black ink material or the photoresist material is applied to form the border, the excessively large thickness of the material complicates the fabrication of the transmission lines. The transmission lines may even encounter the problem of disconnection. To sum up, there are various issues to be resolved if the border is to be made of the non-black ink material.

### SUMMARY OF THE INVENTION

The invention is directed to a touch panel and a touch display panel. Here, a non-black color layer serves as a border of the touch panel and can achieve satisfactory light shielding effects.

In an embodiment of the invention, a touch panel having an active area and a peripheral area that surrounds the active area is provided. The touch panel includes a cover plate, a touch sensing element, a non-black color layer, a plurality of transmission lines, a reflective pattern layer, and a protection layer. The touch sensing element is configured on the cover plate and located in the active area. The non-black color layer is configured on the cover plate and located in the peripheral area. The transmission lines are configured at a side of the non-black color layer away from the cover plate, located in the peripheral area, and electrically connected to the touch sensing element. The reflective pattern layer is configured at the side of the non-black color layer away from the cover plate and at least located in a partial region of the peripheral area which is not covered by the transmission lines. The protection layer is configured at a side of the transmission lines away from the cover plate.

In an embodiment of the invention, a touch display panel that includes the aforesaid touch panel and a display panel is provided. The display panel is configured at a side of the touch panel facing the protection layer.

Based on the above, the non-black color layer and the reflective pattern layer are configured in the peripheral area of the touch panel, and the non-black color layer is located between the reflective pattern layer and the cover plate. At this time, the reflective pattern layer is conducive to shielding light. Thus, it is not necessary to increase the thickness of the non-black color layer in order to sufficiently shield light. Namely, the non-black color layer located in the peripheral area of the touch panel allows the touch panel to have a non-black border and can still achieve satisfactory light shielding effects. Even though the non-black color layer that is configured in the touch panel, the transmission lines of the touch panel can be formed with ease and do not encounter the problem of disconnection.

Other features and advantages of the invention will be further understood from the further technological features disclosed by the embodiments of the invention wherein there are shown and described embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A includes a schematic top view of a touch panel and a schematic cross-sectional view taken along a sectional line I-I′ according to an embodiment of the invention.

FIG. 1B is a schematic view of a touch display panel according to an embodiment of the invention.

FIG. 2 includes a schematic bottom view of an area RA in the touch panel depicted in FIG. 1 and a schematic cross-sectional view taken along a sectional line II-II′.

FIG. 3 is a schematic cross-sectional view illustrating the touch panel of a first embodiment. Here, FIG. 3 is taken along a sectional line A-A′ depicted in FIG. 2.

FIG. 4 is a schematic cross-sectional view illustrating the touch panel of a second embodiment. Here, FIG. 4 is taken along the sectional line A-A′ depicted in FIG. 2.

FIG. 5 is a schematic cross-sectional view illustrating the touch panel of a third embodiment. Here, FIG. 5 is taken along the sectional line A-A′ depicted in FIG. 2.

FIG. 6 is a schematic cross-sectional view illustrating the touch panel of a fourth embodiment. Here, FIG. 6 is taken along the sectional line A-A′ depicted in FIG. 2.

FIG. 7 is a schematic cross-sectional view illustrating the touch panel of a fifth embodiment. Here, FIG. 7 is taken along the sectional line A-A′ depicted in FIG. 2.

FIG. 8 is a schematic cross-sectional view illustrating the touch panel of a sixth embodiment. Here, FIG. 8 is taken along the sectional line A-A′ depicted in FIG. 2.

FIG. 9 is a schematic partial top view illustrating the transmission lines and the reflective pattern layer in the touch panel according to an embodiment of the invention. Here, the transmission lines and the reflective pattern layer are made of the same material layer.

FIG. 10 is a schematic partial top view illustrating the transmission lines and the reflective pattern layer in the touch panel according to another embodiment of the invention. Here, the transmission lines and the reflective pattern layer are made of the same material layer.

### DESCRIPTION OF EMBODIMENTS

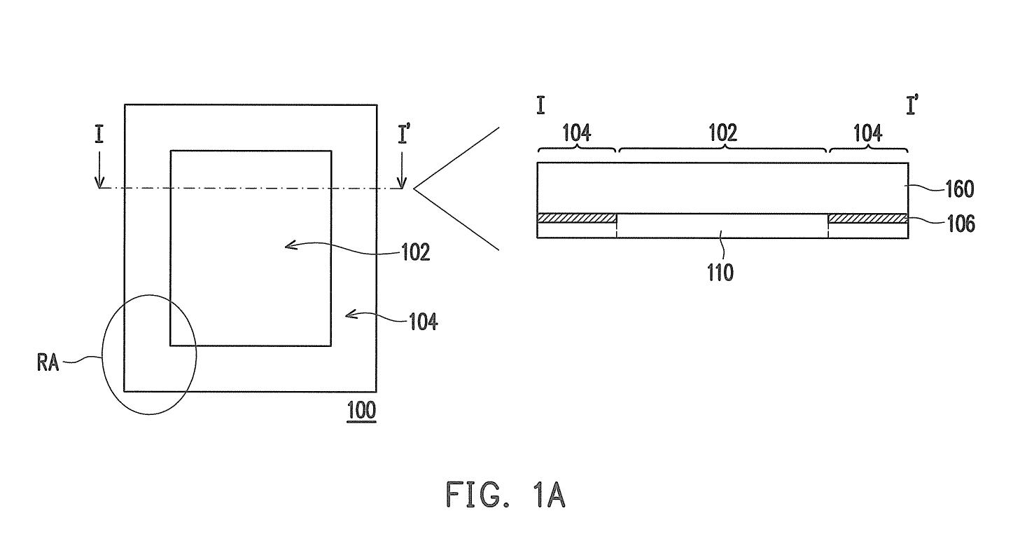

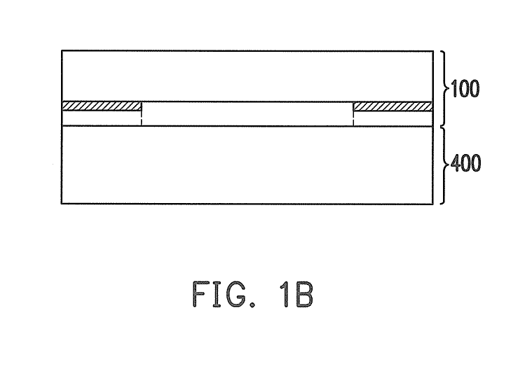

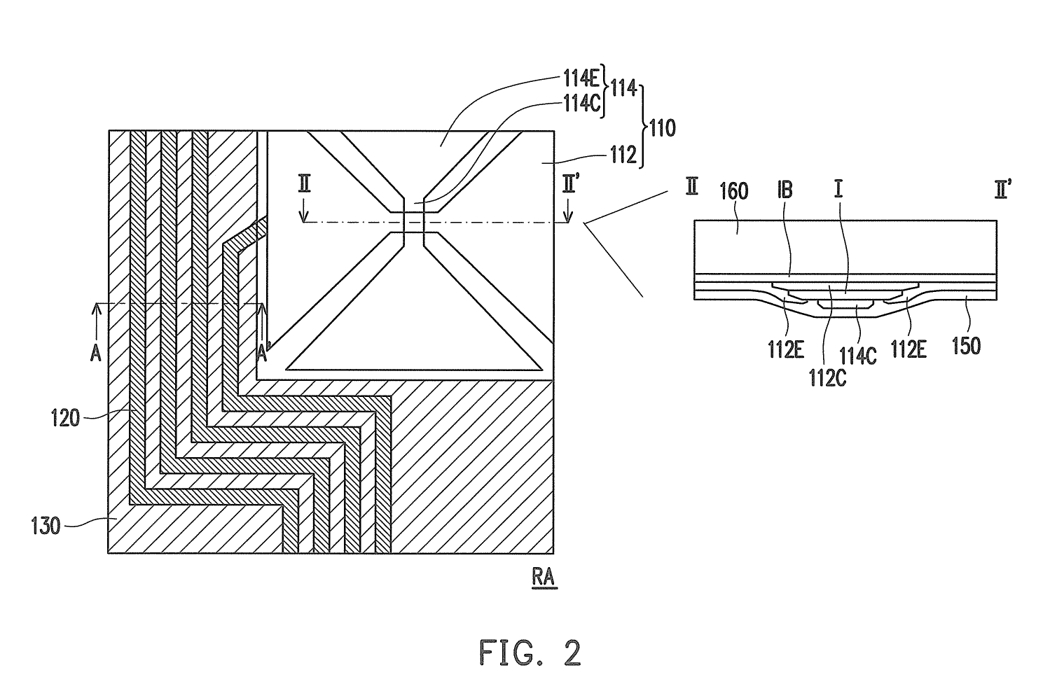

With reference to FIG. 1A, FIG. 1B, and FIG. 2, the touch panel 100 has an active area 102 and a peripheral area 104 surrounding the active area 102. In general, after the touch panel 100 is assembled to a display panel 400 to form a touch display panel, a user is allowed to operate the touch display panel through the active area 102 and view images through the active area 102 due to the transparency property of the active area 102. Here, the display panel 400 is a liquid crystal display (LCD) panel, an organic light emitting display panel, an electrowetting display panel, an electrophoretic display, or any other flat panel display (FPD).

To achieve the touch sensing function, the touch panel 100 includes a touch sensing element 110 that is configured on the cover plate 160, and the touch sensing element 110 is configured in the active area 102. Peripheral element 106 that are constituted by transmission lines 120 and other elements can be configured on the peripheral area 104 of the touch panel 100. Here, the transmission lines 120 are electrically connected to the touch sensing element 110.

As shown in the bottom view of FIG. 2, in addition to the transmission lines 120 in the peripheral area 104, at least a reflective pattern layer 130 is configured in the peripheral area 104 of this embodiment. The reflective pattern layer 130 is at least located in a partial region of the peripheral area 104 which is not covered by the transmission lines 120. Both the reflective pattern layer 130 and the transmission lines 120 are made of a light shielding material.

In this embodiment, the touch sensing element 110 includes a plurality of first sensing series 112 and a plurality of second sensing series 114. The first and second sensing series 112 and 114 respectively extend toward different directions. As indicated in the drawings, each of the first sensing series 112 includes a plurality of first sensing pads 112E and a plurality of first bridge lines 112C, and each of the second sensing series 114 includes a plurality of second sensing pads 114E and a plurality of second bridge lines 114C. The first sensing pads 112E and the first bridge lines 112C are connected, and the second sensing pads 114E and the second bridge lines 114C are connected. The touch sensing element 110 is configured on a bottom insulation layer IB located on the cover plate 160. The first bridge lines 112C and the second bridge lines 114C can be separated by insulation patterns I. The touch sensing element 110 is covered by a protection layer 150. When the display panel 400 and the touch panel 100 are assembled to form the touch display panel, the display panel 400 is configured at a aside of the touch panel 100 facing the protection layer 150. Here, the touch sensing element 110 is configured at one side of the cover plate 160. In other embodiments of the invention, the first and second sensing series 112 and 114 can be respectively configured at two opposite sides of the cover plate 160. In addition, the touch sensing element 110 can be other types of touch sensing element and is not limited to the projected capacitive touch sensing element described in this embodiment. Besides, the shape of the sensing pads is not limited in the invention. For instance, the sensing pads are in a rhombus shape, a triangular shape, or a linear shape.

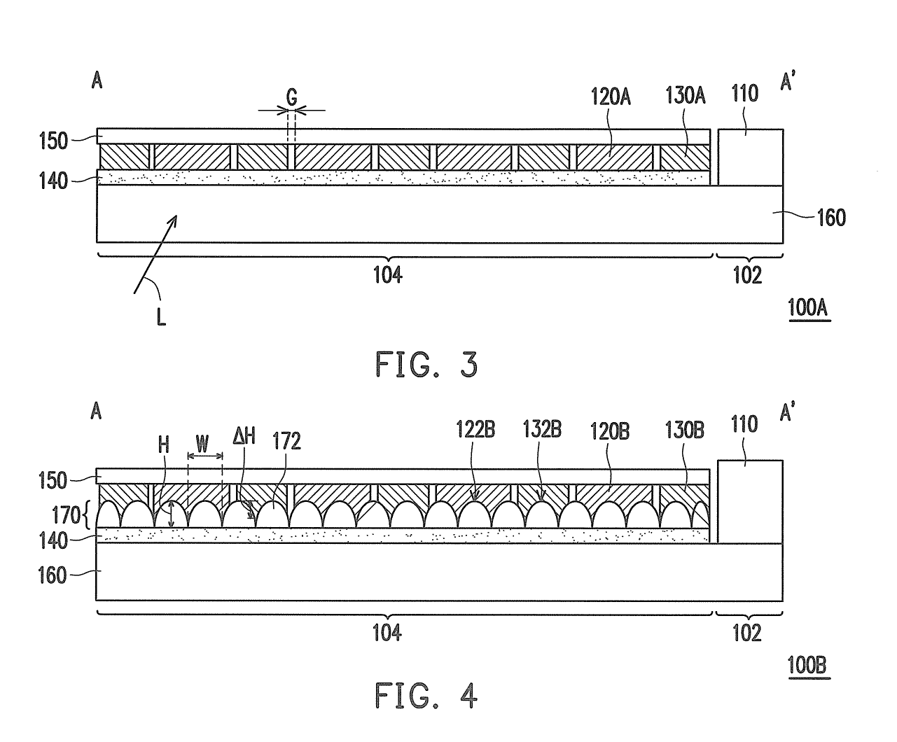

With reference to FIG. 3, the touch panel 100A includes a touch sensing element 110, transmission lines 120A, a reflective pattern layer 130A, a non-black color layer 140, a protection layer 150, and a cover plate 160. In the peripheral area 104 of the touch panel 100A, the non-black color layer 140, the transmission lines 120A, and the protection layer 150 are sequentially configured on the cover plate 160, and the reflective pattern layer 130A and the transmission lines 120A are made of the same material layer. Accordingly, both the transmission lines 120A and the reflective pattern layer 130A are located at a side of the non-black color layer 140 away from the cover plate 160. The protection layer 150 protects the touch sensing element 110 as well as the transmission lines 120A and completely covers the cover plate 160. Here, the protection layer 150 can be made of silicon dioxide, silicon nitride, any other inorganic insulation material, or any other organic insulation material. The cover plate 160 is a transparent glass plate or a plastic substrate.

The material of the non-black color layer 140 includes a non-black photoresist material, a non-black ink material, and a ceramic material, e.g., a white material, a red material, a blue material, and so on. Hence, the peripheral area 104 of the touch panel 100A has a non-black color, e.g., white, red, blue, or other colors required by the user. In addition, the thickness of the non-black color layer 140 ranges from about 0.5 μm to about 50 μm. According to this embodiment, the transmission lines 120A and the reflective pattern layer 130A are configured at a side of the non-black color layer 140 away from the cover plate 160, so as to improve the light shielding performance of the non-black color layer 140.

The transmission lines 120A and the reflective pattern layer 130A can be formed by the same material layer which is made of metal, alloy, a metal stacked layer, an alloy stacked layer, or a layer in which alloy and metal are stacked, such that the transmission lines 120A and the reflective pattern layer 130A can conduct electricity. For instance, the material layer can be made of chromium or a compound thereof, aluminum or a compound thereof, silver or a compound thereof, copper or a compound thereof, gold or a compound thereof, titanium or a compound thereof, tungsten or a compound thereof, molybdenum or a compound thereof, zinc or a compound thereof, or an alloy constituted by the aforesaid metal. The transmission lines 120A and the reflective pattern layer 130A can be formed by forming a non-transparent conductive material layer (not shown) on the non-black color layer 140 with use of the aforesaid material and patterning the non-transparent conductive material layer (not shown) to form the transmission lines 120A and the reflective pattern layer 130A. Here, the patterning process can be photolithography etching or laser cutting. Thereby, the transmission lines 120A and the reflective pattern layer 130A can cover the entire peripheral area 104, such that the peripheral area 104 can have satisfactory light shielding property.

It should be mentioned that each of the transmission lines 120A is required to be electrically independent. Hence, a gap G is between the transmission lines 120A and the reflective pattern layer 130A, and the gap G is larger than 0 μm and is substantially equal to or smaller than 100 μm. Besides, the thickness of the transmission lines 120A and the thickness of the reflective pattern layer 130A range from about 0.05 μm to about 0.5 μm. Therefore, when light L enters the touch panel 100A from the external surroundings, the entire peripheral area 104 can reflect the light L because the peripheral area 104 contains the metallic material.

With reference to FIG. 4, the touch panel 100B includes a cover plate 160, a touch sensing element 110, a non-black color layer 140, a plurality of transmission lines 120B, a reflective pattern layer 130B, a protection layer 150, and a bumpy layer 170. The difference between this embodiment and the first embodiment lies in that the touch panel 100B of this embodiment further includes the bumpy layer 170 that can be made of liquid photoresist or dry film photoresist.

In this embodiment, the bumpy layer 170 has a plurality of bump patterns 172. The height difference ΔH of the bump patterns 172 in the bumpy layer 170 ranges from about 0.1 μm to about 9.9 μm; the maximum thickness H of each bump pattern 172 ranges from about 0.5 μm to about 10 μm; the width W of each bump pattern 172 ranges from about 0.5 μm to about 60 μm. The bump patterns 172 can be regularly or irregularly arranged.

The bumpy layer 170 is configured between the non-black color layer 140 and the reflective pattern layer 130B and between the non-black color layer 140 and the transmission lines 120B. As such, the reflective pattern layer 130B has a first bumpy surface 132B facing the non-black color layer 140, and the transmission lines 120B individually have a second bumpy surface 122B facing the non-black color layer 130 and corresponding to the bumpy layer 170. With the bumpy surfaces, the transmission lines 120B and the reflective pattern layer 130B can reflect light by way of scattering. When the external light L enters the touch panel 100B at a certain angle, the light L is reflected out because the first and second bumpy surfaces 132B and 122B face toward different directions. Said design allows the non-black color layer 140 to have a soft color and allows the touch panel 100B to have an embellished exterior.

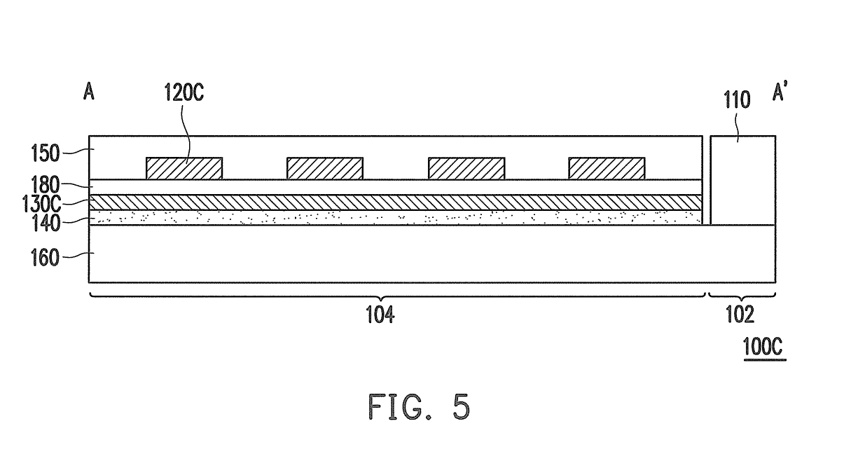

With reference to FIG. 5, the touch panel 100C includes a cover plate 160, a touch sensing element 110, a non-black color layer 140, a plurality of transmission lines 120C, a reflective pattern layer 130C, a protection layer 150, and an insulation layer 180. The difference between this embodiment and the first embodiment lies in that the transmission lines 120C and the reflective pattern layer 130C in the touch panel 100C of this embodiment are constituted by different film layers. Here, the transmission lines 120C and the reflective pattern layer 130C are separated by the insulation layer 180. The materials and the locations of the cover plate 160, the touch sensing element 110, the non-black color layer 140, and the protection layer 150 can be referred to as those described in the first embodiment and thus are not reiterated herein.

In this embodiment, the reflective pattern layer 130C can be made of a non-transparent conductive material, e.g., metal or alloy. To prevent the disconnection of the transmission lines 120C caused by the reflective pattern layer 130C, the transmission lines 120C and the reflective pattern layer 130C are separated by the insulation layer 180 in this embodiment. However, in other embodiments of the invention, the reflective pattern layer 130C can be made of a non-conductive material, e.g., multiple films. At this time, the transmission lines 120C are not electrically connected to the reflective pattern layer 130C, and thus the insulation layer 180 can be selectively omitted in the touch panel 100C.

The reflective pattern layer 130C is located between the transmission lines 120C and the non-black color layer 140. In addition, the reflective pattern layer 130C completely covers the peripheral area 104. Hence, the entire reflective pattern layer 130C is configured at a side of the non-black color layer 140 away from the cover plate 160, such that the peripheral area 104 can have satisfactory light shielding performance. Besides, the reflective pattern layer 130C allows the non-black color layer 140 to have favorable color. When the reflective pattern layer 130C is made of metal, the peripheral area 104 can even shine as metal.

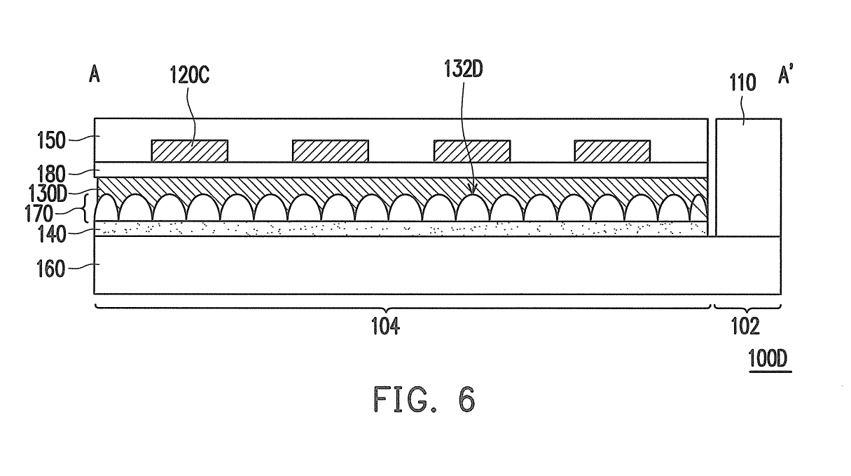

With reference to FIG. 6, the touch panel 100D of this embodiment is similar to the touch panel 100C of the third embodiment (shown in FIG. 5), and the same components in these two embodiments are marked by the same reference numbers and will not be further described. The difference between this embodiment and the third embodiment lies in that the touch panel 100D further includes a bumpy layer 170.

The bumpy layer 170 of this embodiment is similar to the bumpy layer 170 of the second embodiment (shown in FIG. 4). The reflective pattern layer 130D is directly formed on the bumpy layer 170 and has a first bumpy surface 132D facing the non-black color layer 140. With the bumpy surface, the reflective pattern layer 130D can reflect light by way of scattering. Similar to the third embodiment (shown in FIG. 5), this embodiment discloses that the insulation layer 180 can be selectively omitted in the touch panel 100D if the reflective pattern layer 130D is made of a non-metallic material, e.g., multiple films. At this time, the transmission lines 120C can be directly configured on the reflective pattern layer 130D.

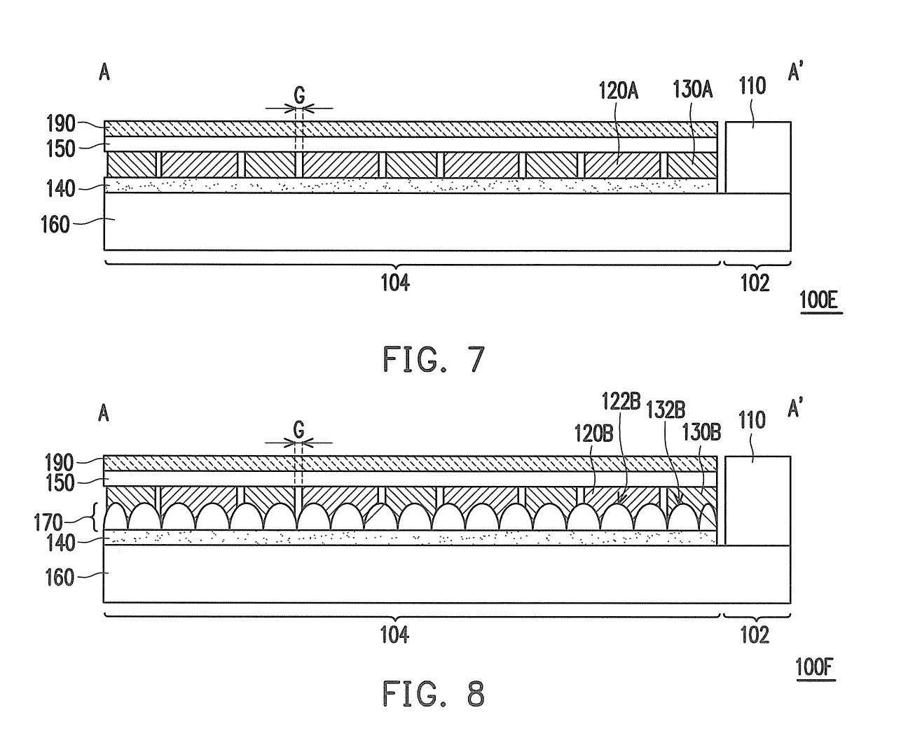

With reference to FIG. 7, the touch panel 100E of this embodiment is similar to the touch panel 100A of the first embodiment (shown in FIG. 3), and the same components in these two embodiments are marked by the same reference numbers and will not be further described. The difference between this embodiment and the first embodiment lies in that the touch panel 100E further includes an auxiliary light shielding layer 190. The auxiliary light shielding layer 190 is configured at a side of the protection layer 150 away from the cover plate 160 and located in the peripheral area 104. Besides, the auxiliary light shielding layer 190 completely covers the peripheral area 104. The material of the auxiliary light shielding layer 190 includes an ink material, a photoresist material, or any other reflective material. Here, the material of the auxiliary light shielding layer 190 can be white or black. The white material includes titanium dioxide particles or silicon dioxide particles, and the black material can be carbon glue. The thickness of the auxiliary light shielding layer 190 ranges from about 0.3 μm to about 5 μm.

In this embodiment, the auxiliary light shielding layer 190 completely covers the peripheral area 104. Namely, light in the gap G between the transmission lines 120A and the reflective pattern layer 130A can be shielded by the auxiliary light shielding layer 190, and the entire peripheral area 104 of the touch panel 100E can have satisfactory light shielding performance.

With reference to FIG. 8, the difference between this embodiment and the second embodiment lies in that the touch panel 100F further includes an auxiliary light shielding layer 190. The auxiliary light shielding layer 190 is configured at a side of the protection layer 150 away from the cover plate 160 and located in the peripheral area 104. Besides, the auxiliary light shielding layer 190 completely covers the peripheral area 104. The design of the auxiliary light shielding layer 190 can be referred to as that described in the fifth embodiment (shown in FIG. 7) and is thus not reiterated herein.

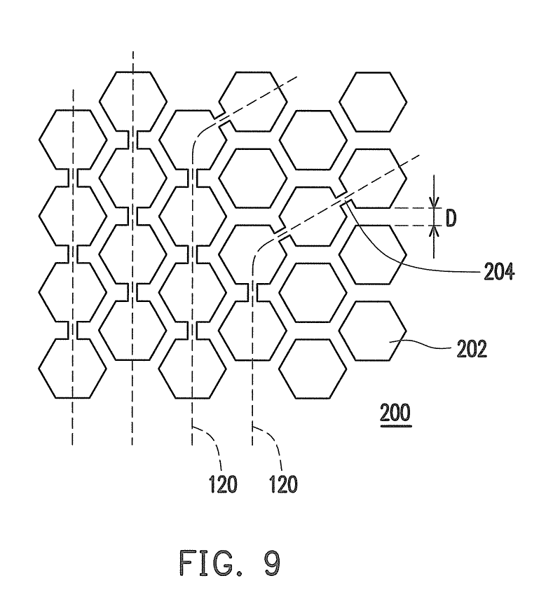

With reference to FIG. 9, the material layer 200 defines a plurality of polygonal patterns 202. A distance D is between the polygonal patterns 202 adjacent to each other, and the distance D is longer than 0 μm and is substantially equal to or shorter than 100 μm. In this embodiment, the material layer 200 is formed by patterning metal, alloy, a metal stacked layer, an alloy stacked layer, or a layer in which alloy and metal are stacked. The polygonal patterns 202 shown in the drawings are hexagonal patterns, while the polygonal patterns 202 can also be quadrilateral patterns, pentagonal patterns, and so on, which should not be construed as a limitation to the invention. It should be mentioned that the patterns of the material layer 200 are designed on the condition that the transmission lines and the reflective patterns in the touch panel are formed by the same material layer, and therefore the pattern design of the material layer 200 can be applied to the touch panel described in the first, second, fifth, and sixth embodiments.

When the material layer 200 is applied to the touch panel 100 depicted in FIG. 1, some of the polygonal patterns 202 can be electrically connected by connection patterns 204, so as to form the transmission lines 120 shown in FIG. 2. The other polygonal patterns 202 form the reflective pattern layer 130 shown in FIG. 2. The connection patterns 204 and the polygonal patterns 202 can be in the same film layer or in different film layers. In this embodiment, the material layer 200 is patterned to form a plurality of polygonal patterns 202 that are regularly or irregularly arranged, and the required conductive path can be formed in consideration of the connection correlation of the polygonal patterns 202. The other polygonal patterns form the reflective pattern layer described in the previous embodiments.

Since the distance D between the adjacent polygonal patterns 202 is set within a certain range, the polygonal patterns 202 can cover the entire peripheral area 104 of the touch panel 100, such that the polygonal patterns 202 in the peripheral area 104 can achieve satisfactory light shielding effects when the polygonal patterns 202 are applied to the touch panel 100. Hence, when the touch panel 100 has the cross-sectional structure shown in FIG. 3, FIG. 4, FIG. 7, or FIG. 8, the touch panel 100 can have a non-black color border, and the conductive wires in the peripheral area 104 are not observed by the user.

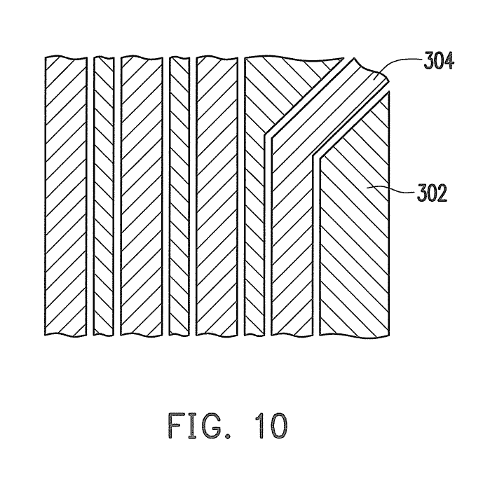

With reference to FIG. 10, the material layer 300 defines a plurality of linear patterns 302 and 304. When the material layer 300 is applied to the touch panel 100 depicted in FIG. 1 or FIG. 2, the linear patterns 304 constitute the transmission lines 120 in the touch panel 100 to be electrically connected to the touch sensing element 110, and the linear patterns 302 constitute the reflective pattern layer 130 in the touch panel 100. Since the linear patterns 302 cover the regions which are not covered by the linear patterns 304, the material layer 300 in the peripheral area 104 can accomplish satisfactory light shielding effects when the material layer 300 is applied to the touch panel 100 depicted in FIG. 1 or FIG. 2. Hence, when the touch panel 100 has the cross-sectional structure shown in FIG. 3, FIG. 4, FIG. 7, or FIG. 8, the touch panel 100 can have a non-black color border, and the conductive wires in the peripheral area 104 are not observed by the user.

In addition, the linear patterns 304 are not limited to straight lines. Namely, the linear patterns 304 can be zigzag patterns or curved patterns. The linear patterns 302 in the material layer 300 can be geometric patterns or other types of linear patterns. As long as the patterns of the material layer 300 are designed to cover the peripheral area 104 and ensure that the transmission lines 120 are electrically independent, the material layer 300 can be applied to the touch panel 100. For instance, the material layer can include a plurality of linear patterns and a plurality of polygonal patterns. The linear patterns define the transmission lines, and the polygonal patterns located among the linear patterns define the reflective pattern layer.

In light of the foregoing, the non-black color layer is configured in the peripheral area of the touch panel or the peripheral area of the touch display panel to form the non-black border. Moreover, the reflective pattern layer is configured at a side of the non-black color layer away from the cover plate, such that the peripheral area is completely covered by the reflective material. Consequently, the peripheral area of the touch panel can have the non-black color and can have favorable light shielding performance, and thereby the user's requirement for the exterior of the apparatus can be satisfied.

Although the invention has been described with reference to the above embodiments, it will be apparent to one of the ordinary skill in the art that modifications to the described embodiments may be made without departing from the spirit of the invention. Accordingly, the scope of the invention will be defined by the attached claims rather than by the above detailed descriptions.

What is claimed is:

1. A touch panel having an active area and a peripheral area surrounding the active area, the touch panel comprising:
a cover plate;
a touch sensing element configured on the cover plate and located in the active area;
a non-black color layer configured on the cover plate and located in the peripheral area;
a plurality of transmission lines configured at a side of the non-black color layer away from the cover plate, located in the peripheral area, and electrically connected to the touch sensing element;
a reflective pattern layer configured at the side of the non-black color layer away from the cover plate and at least located in a partial region of the peripheral area not covered by the transmission lines; and
a protection layer configured at a side of the transmission lines away from the cover plate.

2. The touch panel as recited in claim 1, wherein the transmission lines and the reflective pattern layer are made of a same material layer.

3. The touch panel as recited in claim 2, wherein a gap is between the transmission lines and the reflective pattern layer, and the gap is larger than 0 μm and is substantially equal to or shorter than 100 μm.

4. The touch panel as recited in claim 2, wherein the material layer defines a plurality of polygonal patterns, a distance is between the polygonal patterns adjacent to each other, and the distance is longer than 0 μm and is substantially equal to or shorter than 100 μm.

5. The touch panel as recited in claim 4, wherein parts of the polygonal patterns are electrically connected to the touch sensing element to form the transmission lines, and the other parts of the polygonal patterns form the reflective pattern layer.

6. The touch panel as recited in claim 4, wherein the material layer further defines a plurality of linear patterns to form the transmission lines, and the polygonal patterns located among the transmission lines form the reflective pattern layer.

7. The touch panel as recited in claim 2, wherein the material layer defines a plurality of linear patterns, a distance is between the linear patterns adjacent to each other, the distance is longer than 0 μm and is substantially equal to or shorter than 100 μm, parts of the linear patterns are electrically connected to the touch sensing element to form the transmission lines, and the other parts of the linear patterns form the reflective pattern layer.

8. The touch panel as recited in claim 1, further comprising an insulation layer configured between the reflective pattern layer and the transmission lines, the reflective pattern layer being located between the transmission lines and the non-black color layer.

9. The touch panel as recited in claim 8, wherein a material of the reflective pattern layer is metal.

10. The touch panel as recited in claim 1, wherein the reflective pattern layer is formed by multiple films, and the reflective pattern layer is located between the transmission lines and the non-black color layer.

11. The touch panel as recited in claim 1, further comprising a bumpy layer having a plurality of bump patterns, the bumpy layer being configured between the non-black color layer and the reflective pattern layer, such that the reflective pattern layer has a first bumpy surface facing the non-black color layer.

12. The touch panel as recited in claim 11, wherein the transmission lines and the reflective pattern layer are formed by a same film layer, and each of the transmission lines has a second bumpy surface facing the non-black color layer and corresponding to the bumpy layer.

13. The touch panel as recited in claim 1, further comprising an auxiliary light shielding layer configured at a side of the protection layer away from the cover plate and located in the peripheral area, the auxiliary light shielding layer completely covering the peripheral area.

14. The touch panel as recited in claim 13, wherein a material of the auxiliary light shielding layer comprises an ink material or a photoresist material.

15. The touch panel as recited in claim 1, wherein a thickness of the non-black color layer ranges from about 0.5 μm to about 50 μm.

16. The touch panel as recited in claim 15, wherein the cover plate is a glass plate or a plastic plate.

17. The touch panel as recited in claim 1, wherein a material of the non-black color layer comprises a non-black photoresist material, a non-black ink material, or a ceramic material.

18. A touch display panel comprising:
a touch panel having an active area and a peripheral area surrounding the active area, the touch panel comprising:
a cover plate;
a touch sensing element configured on the cover plate and located in the active area;
a non-black color layer configured on the cover plate and located in the peripheral area;
a plurality of transmission lines configured at a side of the non-black color layer away from the cover plate, located in the peripheral area, and electrically connected to the touch sensing element;
a reflective pattern layer configured at the side of the non-black color layer away from the cover plate and at least located in a partial region of the peripheral area not covered by the transmission lines; and
a protection layer configured at a side of the transmission lines away from the cover plate; and
a display panel configured at a side of the touch panel facing the protection layer.

19. The touch display panel as recited in claim 18, wherein the display panel is a liquid crystal display panel, an organic light emitting display panel, an electrowetting display panel, or an electrophoretic display.
